(19) United States
(12) Patent Application Publication
(10) Pub. No.: US 2010/0055856 A1
(43) Pub. Date: Mar. 4, 2010

(54) Method of forming oxide layer, and method of manufacturing semiconductor device

(76) Inventors: Soo-Jin Hong, Hwasung-City (KR); Jong-Ryeol Yoo, Hwasung-City (KR); Dong-Woon Shin, Hwasung-City (KR); Si-Young Choi, Hwasung-City (KR); Sun-Ghil Lee, Hwasung-City (KR)

Correspondence Address: LEE & MORSE, P.C., 3141 FAIRVIEW PARK DRIVE, SUITE 500, FALLS CHURCH, VA, 22042, US

(21) Appl. No.: 12/461,896

(22) Filed: Aug. 27, 2009

(30) Foreign Application Priority Data
Aug. 28, 2008 (KR) 10-2008-0084624

(51) Int. Cl. H01L 21/8242; H01L 21/31

(52) U.S. Cl. 438/239; 438/771; 257/E21.646; 257/E21.24

(57) ABSTRACT

A method of forming an oxide layer on a trench, a method of forming a semiconductor device, and a semiconductor device, the method of forming an oxide layer on a trench including forming a first trench in a first portion of a substrate and a second trench in a second portion of the substrate, the first portion being different from the second portion, performing a plasma doping process on at least one of the first portion and the second portion to implant an impurity therein, and performing an oxidation process to form an oxide layer on the substrate, a thickness of the oxide layer being determined by the impurity implanted in the substrate.

### BACKGROUND

1. Field

Embodiments relate to a semiconductor device, a method of forming an oxide layer, and a method of manufacturing a semiconductor device.

2. Description of the Related Art

As semiconductor devices have become highly integrated, an area of a unit cell in the semiconductor devices may be greatly decreased. As a result, a width of a pattern and a depth of a junction in the unit cell may be reduced. Although the width of the pattern, e.g., an isolation layer, may be reduced, good electrical characteristics should be maintained for the semiconductor devices. In a DRAM device, a liner may be disposed around the isolation layer to improve the electrical characteristics of the semiconductor devices including the isolation layer.

### SUMMARY

Embodiments are directed to a semiconductor device, a method of forming an oxide layer, and a method of manufacturing a semiconductor device, which substantially overcome one or more of the drawbacks, limitations, and/or disadvantages of the related art.

It is an embodiment to provide a method of forming an oxide layer that prevents deterioration, e.g., hot electron induced punch-through (HEIP), during formation of an isolation layer.

It is an embodiment to provide a method of manufacturing a semiconductor device having good electrical characteristics.

It is an embodiment to provide a semiconductor device having good electrical characteristics.

At least one of the above may be realized by providing a method of forming an oxide layer on a trench including forming a first trench in a first portion of a substrate and a second trench in a second portion of the substrate, performing a plasma doping process on at least one of the first portion and the second portion to implant an impurity therein, and performing an oxidation process to form an oxide layer on the substrate. The first portion is different from the second portion and a thickness of the oxide layer is determined by the impurity implanted in the substrate.

Performing the plasma doping process may include performing the first plasma doping process on the first portion to implant an oxidation retarding first impurity in the first portion having the first trench. The first impurity may retard the oxidation process.

The first impurity may include a nitrogen atom.

The method may further include forming a first photoresist pattern covering the second portion of the substrate and exposing the first portion of the substrate prior to performing the first plasma doping process.

Performing the plasma doping process may include performing a second plasma doping process on the second portion to implant an oxidation accelerating second impurity in the second portion having the second trench.

The second impurity may include at least one of a Group XVII element and a Group XVIII element on the periodic table.

The second impurity may include at least one of a fluorine atom and an argon atom.

The method may further include forming a second photoresist pattern covering the first portion of the substrate and exposing the second portion of the substrate prior to performing the second plasma doping process.

Performing the plasma doping process may include performing a first plasma doping process on the first portion to implant an oxidation retarding first impurity in the first portion having the first trench, and performing a second plasma doping process on the second portion to implant an oxidation accelerating second impurity in the second portion having the second trench.

Performing the plasma doping process may include forming a first photoresist pattern covering the second portion of the substrate and exposing the first portion of the substrate, performing a first plasma doping process on the first portion using the first photoresist pattern as a mask to implant an oxidation retarding first impurity in the first portion having the first trench, forming a second photoresist pattern covering the first portion of the substrate and exposing the second portion of the substrate, and performing a second plasma doping process on the second portion using the second photoresist pattern as a mask to implant an oxidation accelerating second impurity in the second portion having the second trench.

The performing an oxidation process to form an oxide layer on the substrate may include forming oxide layers on the first and second portions of the substrate, and the oxide layer on the second portion of the substrate may be substantially thicker than the oxide layer on the first portion of the substrate.

The method may further include forming a nitride layer on the oxide layer.

Performing the plasma doping process may include plasma doping with an implantation dose of about 1.0×10¹⁴ atoms/cm² to about 1.0×10¹⁷ atoms/cm².

The first trench and the second trench may each have a width and the width of the second trench may be substantially larger than the width of the first trench.

The first portion may correspond to a cell region and the second portion may correspond to a peripheral region.

Performing the plasma doping process may include plasma doping at a pressure of about 10 torr to about 100 torr.

At least one of the above may also be realized by providing a method of forming a semiconductor device including providing a substrate including a cell region and a peripheral region, forming a first trench in the cell region and a second trench in the peripheral region, performing a plasma doping process on at least one of the cell region and the peripheral region to implant an impurity therein, performing an oxidation process to form an oxide layer on the cell and peripheral regions of the substrate. forming a nitride layer on the oxide layer, and forming an isolation layer on the substrate to fill the first trench and the second trench. A thickness of the oxide layer is determined by the impurity implanted in the substrate,

The method may further include forming a gate structure on the substrate including the isolation layer, forming an insulation interlayer including a contact on the gate structure, and forming a capacitor including a lower electrode, a dielectric layer, and an upper electrode on the contact.

At least one of the above may also be realized by providing a semiconductor device including a substrate including a first trench in a cell region of the substrate and a second trench in a peripheral region of the substrate, the second trench having a substantially larger width than a width of the first trench, an impurity region on a surface of at least one of the first trench and the second trench, an oxide layer on the cell region and the peripheral region of the substrate, and a nitride layer on the oxide layer. The oxide layer on the peripheral region is substantially thicker than the oxide layer on the cell region.

The impurity region may include a first impurity region on the surface of the second trench. The first impurity region may include an oxidation accelerating first impurity.

The impurity region may further include a second impurity region on the surface of the first trench. The second impurity region may include an oxidation retarding second impurity.

The impurity region may include a second impurity region on the surface of the first trench. The second impurity region may include an oxidation retarding second impurity.

### BRIEF DESCRIPTION OF THE DRAWINGS

The above and other features and advantages will become more apparent to those of ordinary skill in the art by describing in detail exemplary embodiments with reference to the attached drawings, in which:

FIGS. 1 and 2 illustrate cross-sectional views of a method of forming an isolation layer and a liner in a trench;

FIG. 3 illustrates a cross-sectional view of a PMOS manufactured according to the method of FIGS. 1 and 2;

FIGS. 4 to 10 illustrate cross-sectional views of a method of forming an oxide layer in accordance with an embodiment;

FIGS. 11 to 15 illustrate cross-sectional views of a method of forming an oxide layer in accordance with another embodiment;

FIGS. 16 to 21 illustrate cross-sectional views of a method of forming an oxide layer in accordance with yet another embodiment;

FIGS. 22 to 34 illustrate cross-sectional views of a method of manufacturing a semiconductor device in accordance with an embodiment; and

FIGS. 35 to 37 illustrate block diagrams of a system including the semiconductor device in accordance with an embodiment.

### DETAILED DESCRIPTION

Korean Patent Application No. 10-2008-0084624, filed on Aug. 28, 2008, in the Korean Intellectual Property Office is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. The term “in” will also be understood to have a comprehensive and inclusive meaning. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

It will be understood that when an element or layer is referred to as being “connected to” or “coupled to” another element or layer, it can be directly connected or coupled to the other element or layer or intervening elements or layers may be present. In contrast, when an element is referred to as being “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

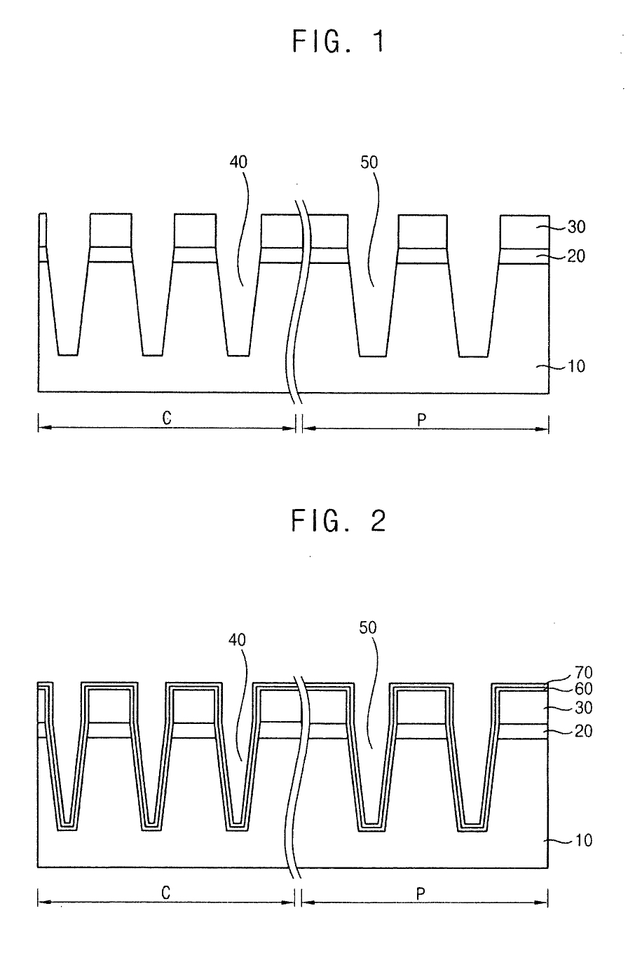

FIGS. 1 and 2 illustrate cross-sectional views of stages in a typical method of forming an isolation layer. Referring to FIG. 1, a substrate 10 may have a cell region C and a peripheral region P. Here, in order to form a CMOS circuit, an NMOS and a PMOS may be formed simultaneously in the peripheral region P and an NMOS may be formed in the cell region C. A pad oxide layer and a hard mask layer may be formed on the substrate 10. The hard mask layer may be patterned using a photoresist pattern as an etching mask to form a hard mask 30. The pad oxide layer and the substrate 10 may be etched using the hard mask 30 as an etching mask to form a pad oxide layer pattern 20, a first trench 40, and a second trench 50.

Referring to FIG. 2, a thermal oxide layer 60 and a liner 70 may be formed along profiles of the first trench 40 and the second trench 50. The thermal oxide layer 60 may prevent oxidation of the liner 70. The liner 70 may reduce or prevent impurities from being diffused into an isolation layer formed in the trenches 40 and 50 to decrease leakage currents and improve electrical characteristics of the semiconductor device.

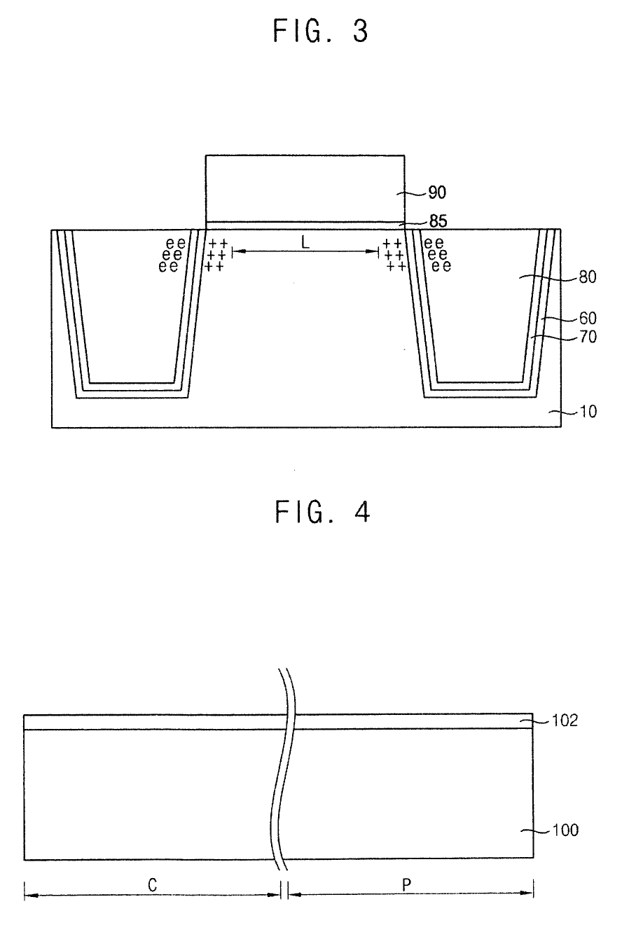

FIG. 3 illustrates a cross-sectional view of a PMOS including a gate oxide layer 85 and a gate electrode 90 disposed on a peripheral region P. The liner 70 may cause deterioration, e.g., a hot electron induced punch-through (HEIP), in the peripheral region on which the PMOS is disposed. Due to the HEIP, electrons may be trapped in an isolation layer 80, obstructing movement of holes, which may be the main carrier of the PMOS. As a result, a channel length L may be decreased, thereby reducing a threshold voltage and increasing an off current. As semiconductor devices become highly integrated, HEIP caused by the liner 70 may occur in the peripheral region P.

FIGS. 4 to 10 illustrate cross-sectional views of a method of forming an oxide layer in accordance with an embodiment. Referring to FIG. 4, a pad oxide layer 102 may be formed on a substrate 100. The substrate 100 may include a semiconductor substrate, e.g., silicon substrate, a germanium substrate, a silicon-germanium substrate, a silicon-on-insulator (SOI) substrate, a germanium-on-insulator (GOI) substrate, etc. Alternatively, the substrate 100 may include a single crystalline metal oxide substrate, e.g., a single crystalline aluminum oxide (Al₂O₃) substrate, a single crystalline strontium titanium oxide (SrTiO₃) substrate, or a single crystalline magnesium oxide (MgO) substrate.

The substrate 100 may include a cell region C in which memory cells may be arranged and a peripheral region P in which circuit cells may be arranged. In order to constitute a CMOS circuit, an NMOS may be formed in the cell region C, and an NMOS and a PMOS may be formed in the peripheral region P. For example, the NMOS may be formed in the cell region C and the NMOS of the peripheral region P may be substantially closer to the cell region C than the PMOS of the peripheral region P.

The pad oxide layer 102 may include, e.g., silicon oxide formed by a thermal oxidation process, a chemical vapor deposition (CVD) process, etc. Various combinations and subcombinations of material and processes may be used. The pad oxide layer 102 may have a thickness of about 50 Å to about 150 Å.

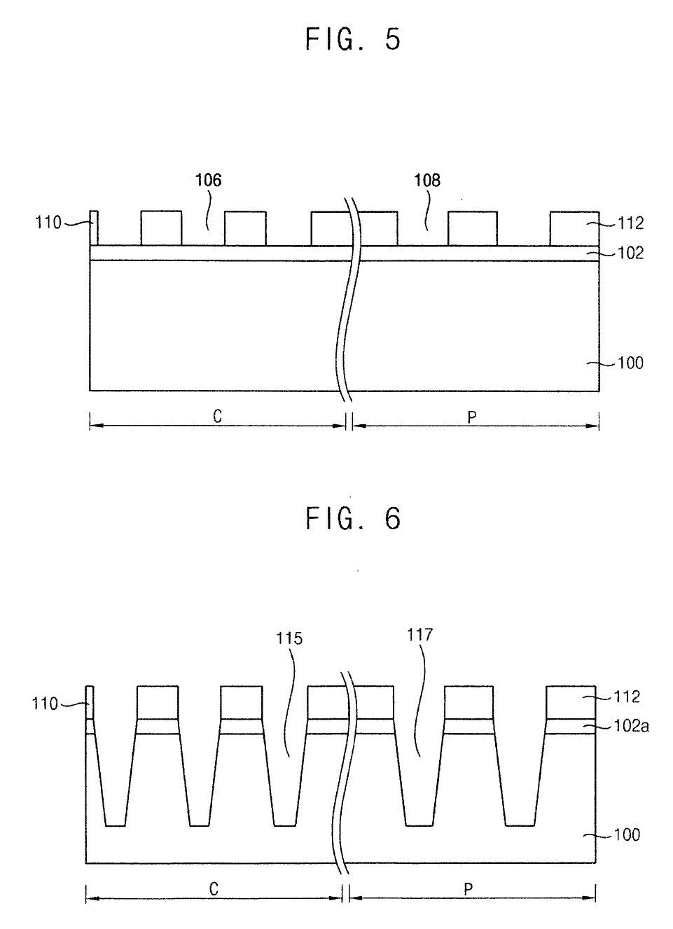

Referring to FIG. 5, a hard mask including first patterns 110 and second patterns 112 may be formed on the pad oxide layer 102. The first patterns 110 may be formed in the cell region C. The first patterns 110 may be separated from each other by a first width. The second patterns 112 may be formed in the peripheral region P. The second patterns 112 may be separated from the each other by a second width that is substantially wider than the first width.

A first opening 106 may be formed between the first patterns 110. A second opening 108 may be formed between the second patterns 112. The second opening 108 may have a width that is substantially wider than a width of the first opening 106. Thus, the first width may be defined by the width of the first opening 106 and the second width may be defined by the width of the second opening 108.

The hard mask including the first patterns 110 and the second patterns 112 may include, e.g., materials having an etching selectivity with respect to the substrate 100 and the pad oxide layer 102. The first patterns 110 and the second patterns 112 may include, e.g., a nitride, an oxide, a carbide, etc. Various combinations and subcombinations of materials may be used. For example, the first patterns 110 and the second patterns 112 may have a single-layer structure or a multilayer structure including the above-mentioned materials having the etching selectivity with respect to the substrate 100 and the pad oxide layer 102.

Referring to FIG. 6, the pad oxide layer 102 and the substrate 100 may be etched using the hard mask including the first patterns 110 and the second patterns 112 as a mask to form a pad oxide layer pattern 102a, a first trench 115, and a second trench 117. In other words, the substrate 100 may be etched through the first opening 106 and the second opening 108 to form the first trench 115 and the second trench 117, respectively, in the substrate 100.

The first trench 115 may be formed in the cell region C. The first trench 115 may have an upper width that is the same as the first width of the first opening 106. The first trench 115 may have a lower width that is substantially narrower than the first width. The first trench 115 may have a first depth.

The second trench 117 may be formed in the peripheral region P. The second trench 117 may have an upper width that is the same as the second width of the second opening 108. The second trench 117 may have a lower width that is substantially narrower than the second width. The second trench 117 may have a second depth. The second depth may be the same as the first depth.

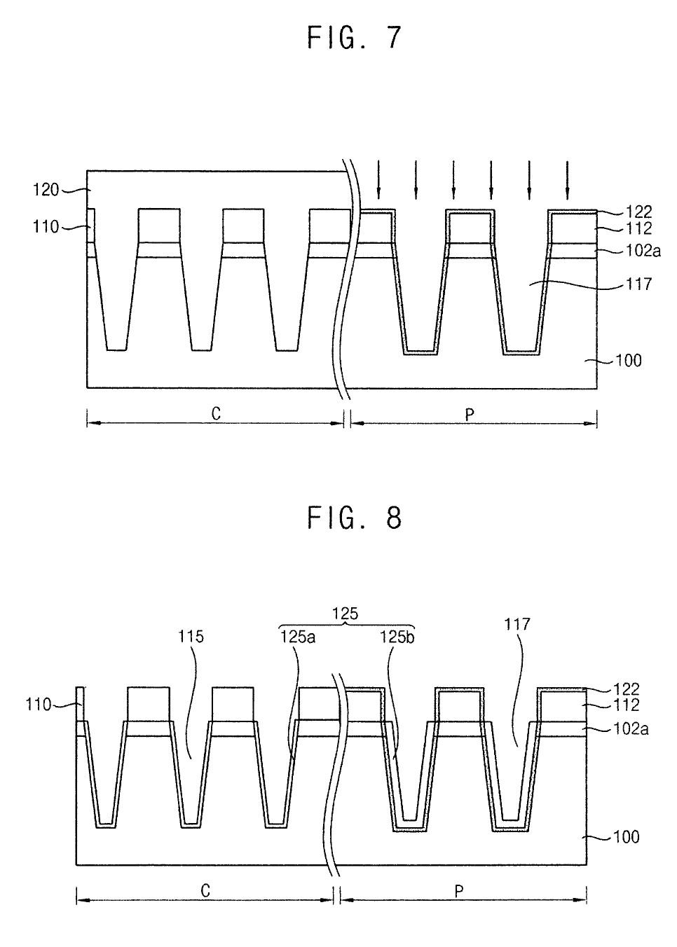

Referring to FIG. 7, a photoresist pattern 120 may be formed on the cell region C. The photoresist pattern 120 may cover the cell region C and expose the peripheral region P.

A plasma doping process may be performed on the peripheral region P of the substrate 100 using the photoresist pattern 120 as an implant mask. In other words, the doping may be performed only on the peripheral region P. The plasma doping process may implant a first impurity in the peripheral region P including the second trench 117. The plasma doping process may include plasma doping at an implantation dose of about 1.0×10¹⁴ atoms/cm² to about 1.0×10¹⁷ atoms/cm². The plasma doping process may be performed at a pressure of about 10 torr to about 100 torr. An impurity region 122 may be formed on surfaces of the second patterns 112 and along profiles of the second trench 117 by the plasma doping process.

The first impurity may accelerate a subsequent oxidation process. Thus, when an oxide layer is formed in a single atmosphere, the oxide layer on a portion of the substrate 100 into which the first impurity has been implanted may be substantially thicker than the oxide layer on a portion of the substrate 100 into which the first impurity has not been implanted. The first impurity may include, e.g., a Group XVII element and/or a Group XVIII element. In other words, the first impurity may include, e.g., a halogen or a noble gas. In an implementation, the first impurity may include, e.g., a fluorine atom and/or an argon atom.

When the first impurity is implanted by the plasma doping process, the first impurity may be uniformly implanted into the peripheral region P including the second trench 117. Thus, when an oxide layer 125 (see FIG. 8) is formed on the second trench 117 in a subsequent process, a thick second oxide layer 125b having a uniform thickness may be formed along the surface of the second trench 117.

The ion implantation process may be easily influenced by, e.g., an angle of impurity implantation, an energy, a state of the substrate 100, etc. If not properly performed, the first impurity may not be uniformly implanted on the peripheral region P having the second trench 117. Thus, the first impurity may be implanted only on an upper portion or a lower portion of the second trench 117, i.e., not conformally implanted along the surface of the second trench 117. As a result, when the oxide layer 125 is formed on the second trench 117 in the subsequent process, it may not have a uniform thickness on the second trench 117.

In an implementation, the photoresist pattern 120 may expose the whole peripheral region P. Accordingly, the plasma doping process may be performed on the whole peripheral region P. In another implementation, the photoresist pattern 120 may only partially expose a portion of the peripheral region P on which the PMOS is to be formed. That is, the photoresist pattern 120 may cover a portion of the peripheral region P on which the NMOS is to be formed. When the photoresist pattern 120 exposes only a portion of the peripheral region P on which the PMOS is to be formed, the plasma doping process may be performed on only the portion exposed by the photoresist pattern 120. After performing the plasma doping process, the photoresist pattern 120 may be removed.

Referring to FIG. 8, the oxide layer 125 including a first oxide layer 125a and the second oxide layer 125b may then be formed on the substrate 100 including the cell region C and the peripheral region P. The first oxide layer 125a may be formed on the cell region C and the second oxide layer 125b may be formed on the peripheral region P.

The oxide layer 125 may be conformally formed along profiles of the first trench 115 and the second trench 117. Thus, the oxide layer 125 may not fill up the first trench 115 and the second trench 117. If the substrate 100 is damaged during formation of the first trench 115 and the second trench 117, the oxide layer 125 may at least partially cure the damage to the substrate 100.

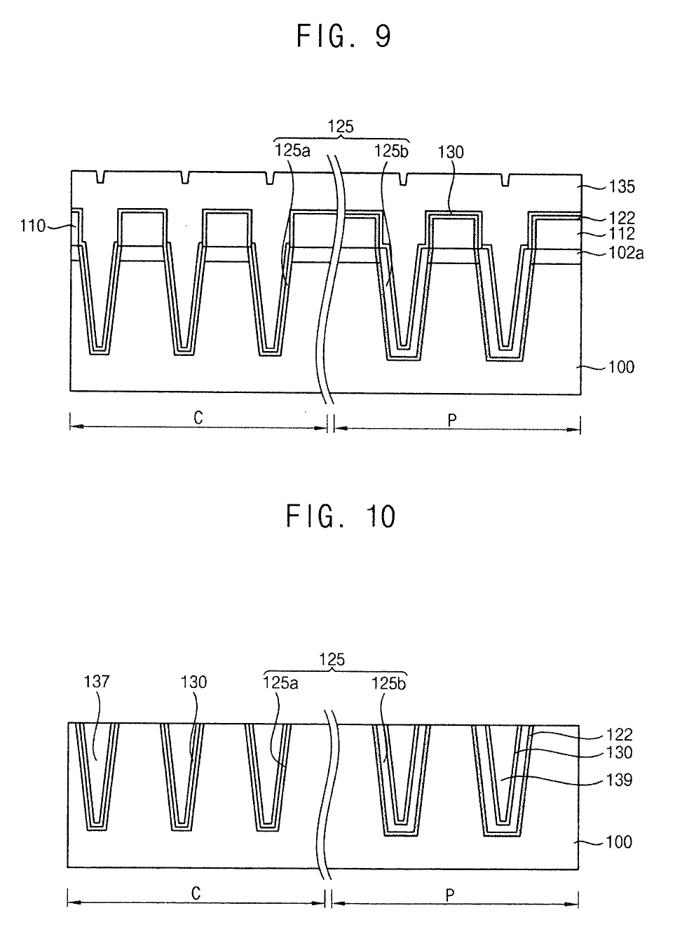

In the finished semiconductor device, the cell region C may include the NMOS and the peripheral region P may include the PMOS and the NMOS. Thus, any deterioration, e.g., HEIP, caused by a liner 130 (see FIG. 9) formed in a subsequent process may be confined to the peripheral region P including the PMOS. However, the deterioration may be prevented by forming the oxide layer with a sufficient thickness. That is, the second oxide layer 125b on the peripheral region P may be sufficiently thick in order to prevent the deterioration of a gate structure.

The thickness of the oxide layer 125 may depend upon the first impurity implanted during the plasma doping process. The first impurity may accelerate the oxidation process. Accordingly, the thickness of the oxide layer 125 on a portion of the substrate 100 into which the oxidation accelerating first impurity has been implanted may be substantially thicker than the oxide layer 125 on a portion of the substrate into which the first impurity has not been implanted.

As mentioned above, the first impurity may be implanted into the peripheral region P including the second trench 117. Thus, when the oxidation process is performed on both the cell region C and the peripheral region P at the same time, the thickness of the second oxide layer 125b on the peripheral region P may be thicker. The second oxide layer 125b may be thick enough to prevent deterioration, e.g., HEIP, in the peripheral region P including the PMOS. The thickness of the first oxide layer 125a on the cell region C may substantially thinner. For example, the second oxide layer 125b on the peripheral region P may have a thickness of about 100 Å to about 200 Å and the first oxide layer 125a on the cell region C may have a thickness less than about 100 Å.

The first impurity may be implanted by the plasma doping process. As a result, the first impurity may be uniformly implanted along profiles of the surface of the second trench 117. Thus, the second oxide layer 125b on the second trench 117 may have a uniform thickness.

In an implementation, the oxide layer 125 may be formed by, e.g., a thermal oxidation process. For example, the oxide layer 125 may be formed by a radical oxidation process using a furnace or rapid thermal oxidation process. When the oxide layer 125 is formed by the thermal oxidation process, portions of the substrate 100 exposed by the first trench 115 and the second trench 117 may be thermally oxidized to form the oxide layer 125 on sidewalls and lower faces of the first trench 115 and the second trench 117. The oxide layer 125 may extend over side surfaces of the pad oxide layer pattern 102a.

In another implementation, the oxide layer 125 may be formed by, e.g., a CVD process. When the oxide layer 125 is formed by the CVD process, the oxide layer 125 may be conformally formed along profiles of the first trench 115, the second trench 117, and the hard mask including the first patterns 110 and the second patterns 112.

Referring to FIG. 9, the liner 130 may be formed on the oxide layer 125. The liner 130 may be conformally formed on the oxide layer 125 along profiles of the first trench 115 and the second trench 117. Thus, the liner 130 may not completely fill up the first trench 115 and the second trench 117. An isolation layer 135 may be formed on the liner 130 to fill the first trench 115 and the second trench 117. The liner 130 may reduce or prevent impurities from diffusing into the isolation layer 135. The liner 130 may include, e.g., a nitride formed by a low pressure chemical vapor deposition (LPCVD) process. Alternatively, other processes may be used.

The isolation layer 135 may include, e.g., an oxide, a nitride, etc. In an implementation, the isolation layer 135 may include, e.g., silicon oxide, having superior gap-filling characteristics. For example, the isolation layer 135 may include borophosphosilicate glass (BPSG), phosphosilicate glass (PSG), undoped silicate glass (USG), spin-on glass (SOG), flowable oxide (FOx), tetraethyl orthosilicate (TEOS), plasma-enhanced tetraethyl orthosilicate (PE-TEOS), high-density plasma chemical vapor deposition (HDP-CVD) oxide, etc. These may used alone or in a combinations/subcombinations thereof. The isolation layer 135 may be formed by, e.g., a chemical vapor deposition (CVD) process, a low-pressure chemical vapor deposition (LPCVD) process, a plasma-enhanced chemical vapor deposition (PECVD) process, an HDP-CVD process, etc.

Referring to FIG. 10, the pad oxide layer pattern 102a, the hard mask, and portions of the isolation layer 135 may be removed such that a portion of the substrate 100 is exposed. A first isolation layer pattern 137 in the cell region C and a second isolation layer pattern 139 in the peripheral region P may remain to fill the first trench 115 and the second trench 117, respectively. The pad oxide layer pattern 102a, the hard mask, and the isolation layer 135 may be removed by, e.g., a chemical mechanical polishing (CMP) process and/or an etch-back process.

The first isolation layer pattern 137, the thin first oxide layer 125a, and the liner 130 may be disposed on the cell region C; and the second isolation layer pattern 139, the thick second oxide layer 125b, and the liner 130 may be disposed on the peripheral region P. Additionally, the peripheral region P may include the impurity region 122 in the substrate 100 adjacent the thick second oxide layer 125b. The impurity region 122 may include the oxidation accelerating first impurity.

The isolation layer patterns 137 and 139 may divide the substrate 100 into an active region and an inactive region. A gate structure may be formed on the active region.

The thin first oxide layer 125a may be formed on the cell region C and the thick second oxide layer 125b may be formed on the peripheral region P by a single oxidation process. That is, the oxidation accelerating first impurity may be implanted in the peripheral region P prior to the oxidation process. Then, when the oxidation process is performed on the substrate 100, the second oxide layer 125b on the peripheral region P may selectively have a thick thickness because the first impurity in the peripheral region P may accelerate the oxidation process.

Additionally, the first impurity may be uniformly implanted by the plasma doping process along profiles of the second trench 117. Thus, the second oxide layer 125b on the peripheral region P including the second trench 117 may have a uniform thickness. Thus, deterioration of a semiconductor device may be prevented so that the semiconductor device may have good electrical characteristics and reliability.

Hereinafter, a method of forming an oxide layer according to another embodiment will be explained in detail with reference to the accompanying drawings.

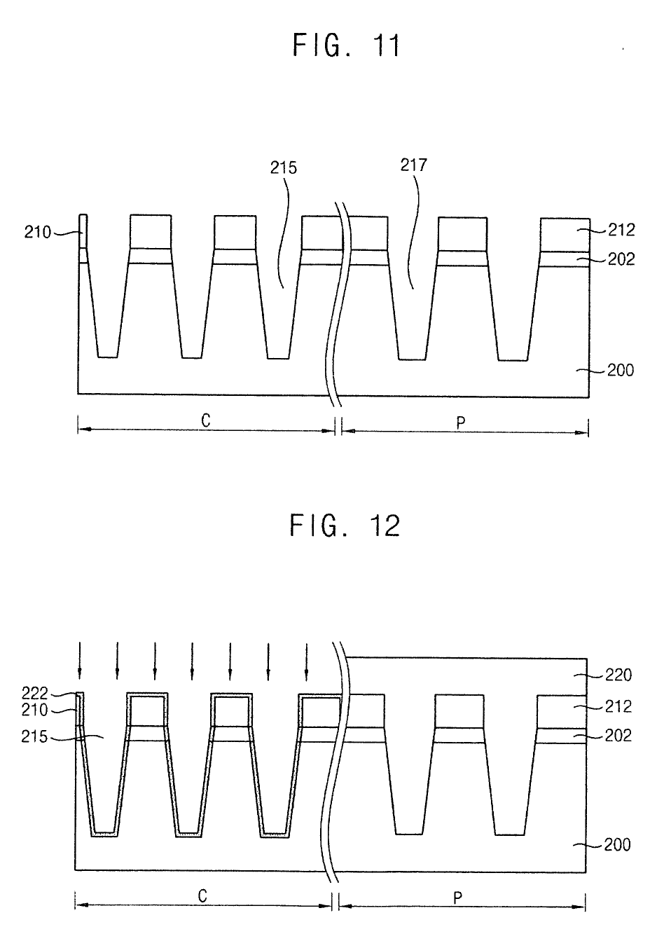

FIGS. 11 to 15 illustrate cross-sectional views of a method of forming an oxide layer in accordance with the embodiment. Referring to FIG. 11, a substrate 200 including a cell region C and a peripheral region P may be provided. The substrate 200 may include a cell region C in which memory cells may be arranged and a peripheral region P in which circuit cells may be arranged. In order to constitute a CMOS circuit, an NMOS may be formed in the cell region C and an NMOS and a PMOS may be formed in the peripheral region P. For example, the NMOS may be formed in the cell region C and the NMOS of the peripheral region P may be substantially closer to the cell region C than the PMOS of the peripheral region P.

The substrate 200 may include a pad oxide layer pattern 202 and a hard mask including first patterns 210 on the cell region C and second patterns 212 on the peripheral region P. A first trench 215 and a second trench 217 may be formed in the substrate 200. The first trench 215 may be formed in the cell region C and the second trench 217 may be formed in the peripheral region P. The first trench 215 may have a first width and the second trench 217 may have a second width. The second width may be substantially wider than the first width.

The hard mask, the pad oxide layer pattern 202, and the first and second trenches 215 and 217 may be formed by the same or a similar process to those described with reference to FIGS. 4 to 6. Thus, further detailed description of the processes forming the hard mask, the pad oxide layer pattern 202, and the first and second trenches 215 and 217 is omitted.

Referring to FIG. 12, a photoresist pattern 220 may be formed on the peripheral region P. The photoresist pattern 220 may cover the peripheral region P and may expose the cell region C.

A plasma doping process may be performed on the cell region C of the substrate 200 to implant a second impurity using the photoresist pattern 220 as an implant mask. In other words, the doping may be performed only on the peripheral regions P. The plasma doping process may include plasma doping at an implantation dose of about 1.0×10¹⁴ atoms/cm² to about 1.0×10¹⁷ atoms/cm². The plasma doping process may be performed at a pressure of about 10 torr to about 100 torr. An impurity region 222 may be formed on surfaces of the first patterns 210 and along profiles of the first trench 215 by the plasma doping process. The second impurity may include, e.g., a nitrogen atom.

The second impurity may retard a subsequent oxidation process. Therefore, when an oxide layer 225 (see FIG. 13) is formed in a single atmosphere, the oxide layer formed on a portion of the substrate 200 into which the second impurity has been implanted may be substantially thinner than the oxide layer formed on a portion of the substrate 200 into which the second impurity has not been implanted.

When the second impurity is implanted by the plasma doping process, it may be uniformly implanted into the cell region C including the first trench 215 having the narrow first width and a high aspect ratio. Even when the first trench 215 has a high aspect ratio, the second impurity may be conformally implanted along a surface of the first trench 215 by the plasma doping process. Thus, when the oxide layer 225 is formed on the first trench 215 in a subsequent process, a thin oxide layer having a uniform thickness may be formed along the surface of the first trench 215 on the cell region C. After performing the plasma doping process, the photoresist pattern 220 may be removed from the peripheral region P.

The ion implantation process may be easily influenced by, e.g., an angle of the impurity implantation, an energy, a state of the substrate 200, etc., and, if not properly performed, the second impurity may not be uniformly implanted on the cell region C having the first trench 215. Thus, when the first trench 215 has a high aspect ratio, the second impurity may be implanted only on an upper portion or a lower portion of the first trench 215, i.e., not conformally implanted along the surface of the first trench 215. Therefore, when the oxide layer 225 is formed on the first trench 215 of the cell region C in a subsequent process, a thin oxide layer having a uniform thickness may not be formed on the first trench 215.

Referring to FIG. 13, the oxide layer 225 including a first oxide layer 225a and a second oxide layer 225b may be formed on the substrate 200 including the cell region C and the peripheral region P. The first oxide layer 225a may be disposed on the cell region C and the second oxide layer 225b may be disposed on the peripheral region P.

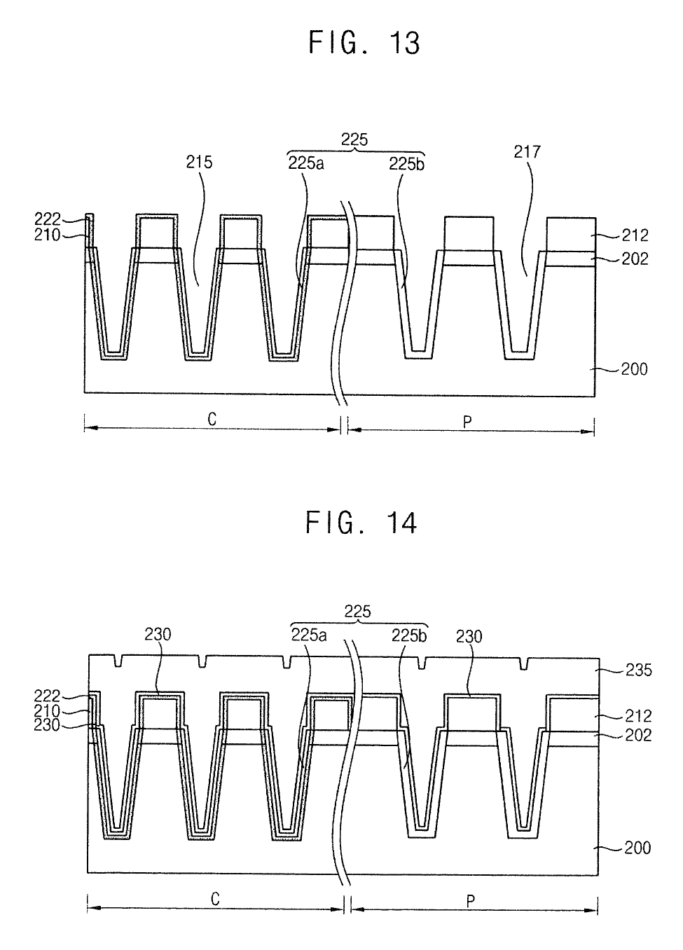

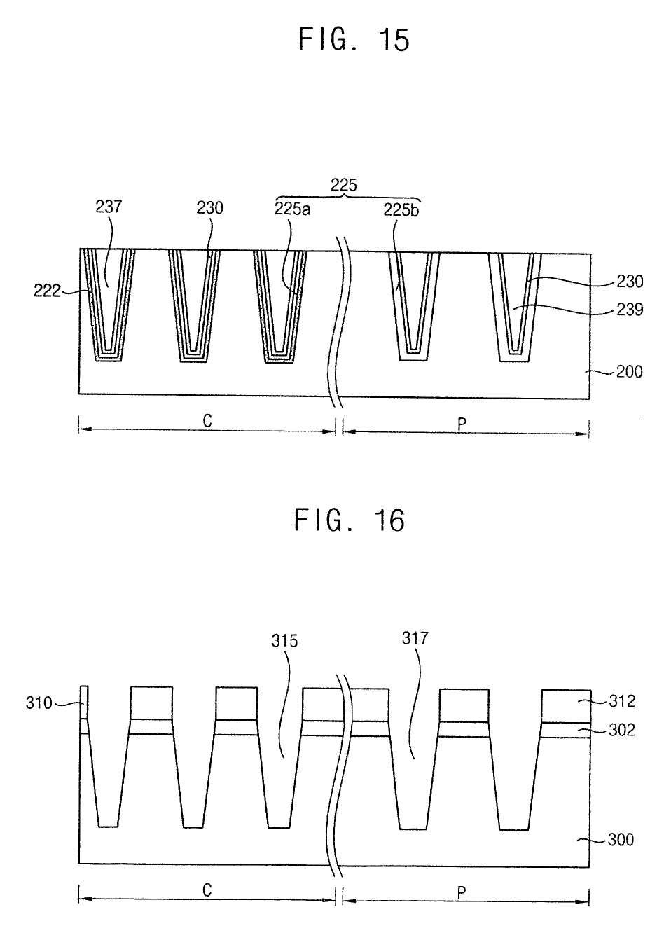

The cell region C may include the NMOS and the peripheral region P may include the PMOS and the NMOS. Thus, any deterioration, e.g., HEIP, caused by a liner 230 (see FIG. 14) formed in a subsequent process may be confined to the peripheral region P including the PMOS. However, the deterioration may be prevented by forming the oxide layer having a sufficient thickness. That is, the second oxide layer 225b on the peripheral region P may be sufficiently thick in order to prevent deterioration. Meanwhile, deterioration may not occur in the cell region C including only the NMOS without PMOS. Further, the first trench 215 in the cell region C may have the narrow first width and high aspect ratio. If the oxide layer 225a on the cell region C is thick, the first oxide layer 225a may not be conformally formed along profiles of the first trench 215. Accordingly, the first oxide layer 225a on the cell region C should be sufficiently thin, because the cell region C may include the first trench 215 having the narrow width and high aspect ratio. Thus, the first oxide layer 225a on the cell region C may be relatively thin and the second oxide layer 225b on the peripheral region P may be relatively thick.

A thickness of the oxide layer 225 may be adjusted or determined based upon the impurity implanted. The second impurity may retard the oxidation process. Accordingly, the thickness of the oxide layer on a portion of the substrate 200 into which the second impurity has been implanted may be substantially thinner than the thickness of the oxide layer on a portion of the substrate 200 into which the second impurity has not been implanted.

As mentioned above, the oxidation retarding second impurity may be implanted into the cell region C. Thus, when the oxidation process is performed on both the cell region C and the peripheral region P at the same time, the thickness of the first oxide layer 225a on the cell region C may be relatively thin while the thickness of the second oxide layer 225b on the peripheral region P may be thick enough to prevent deterioration in the peripheral region P including the PMOS. For example, the second oxide layer 225b on the peripheral region P may have a thickness of about 100 Å to about 200 Å; and the first oxide layer 225a on the cell region C may have a thickness less than about 100 Å.

As mentioned above, the second impurity may be uniformly implanted by the plasma doping process. As a result, the second impurity may be implanted along profiles of the surface of the first trench 215; and thus the first oxide layer 225a on the first trench 215 may have a uniform thickness.

Referring to FIG. 14, the liner 230 and an isolation layer 235 may be formed on the oxide layer 225. The liner 230 may be conformally formed on the oxide layer 225 along profiles of the first trench 215 and the second trench 217. The isolation layer 235 may be formed on the liner 230 to fill the first trench 215 and the second trench 217. The isolation layer 235 may include, e.g., an oxide, a nitride, etc. In an implementation, the isolation layer 235 include, e.g., silicon oxide, having superior gap-filling characteristics.

Referring to FIG. 15, the pad oxide layer pattern 202, the hard mask, and portions of the isolation layer 235 may be removed such that a portion of the substrate 200 is exposed. A first isolation layer pattern 237 in the cell region C and the second isolation layer pattern 239 in the peripheral region P may remain to fill the first trench 215 and the second trench 217, respectively. The pad oxide layer pattern 202, the hard mask, and the isolation layer 235 may be removed by, e.g., a CMP process and/or an etch-back process.

The first isolation layer pattern 237, the thin first oxide layer 225a, and the liner 230 may be disposed on the cell region C. The second isolation layer pattern 239, the thick second oxide layer 225b, and the liner 230 may be disposed on the peripheral region P. Additionally, the cell region C may include the impurity region 222 in the substrate 200 adjacent to the thin first oxide layer 225a. The impurity region 222 may include the oxidation retarding second impurity.

The isolation layer patterns 237 and 239 may divide the substrate 200 into an active region and an inactive region. A gate structure may be formed on the active region.

The thin first oxide layer 225a may be formed on the cell region C and the thick second oxide layer 225b may be formed on the peripheral region P by a single oxidation process. The oxidation retarding second impurity may be implanted in the cell region C including the first trench 215 prior to the oxidation process. Thus, when the oxidation process is performed on the substrate 200, the first oxide layer 225a having a thin thickness may be selectively formed on the cell region C because the second impurity in the cell region C may retard the oxidation process.

Additionally, the oxidation retarding second impurity may be uniformly implanted along profiles of the first trench 215 having a high aspect ratio by the plasma doping process. Thus, the first oxide layer 225a on the cell region C including the first trench 215 may have a uniform thickness. Accordingly, deterioration of a semiconductor device may be prevented and the semiconductor device may have good electrical characteristics and reliability.

Hereinafter, a method of forming an oxide layer according to yet another embodiment will be explained in detail with reference to the accompanying drawings.

FIGS. 16 to 20 illustrate cross-sectional views of a method of forming an oxide layer in accordance with the embodiment. Referring to FIG. 16, a substrate 300 including a cell region C and a peripheral region P may be provided. The substrate 300 may include the cell region C in which memory cells may be arranged and the peripheral region P in which circuit cells may be arranged. In order to constitute a CMOS circuit, an NMOS may be formed in the cell region C, and an NMOS and a PMOS may be formed in the peripheral region P. For example, the NMOS may be formed in the cell region C and the NMOS of the peripheral region P may be substantially closer to the cell region C than the PMOS of the peripheral region P.

The substrate 300 may include a pad oxide layer pattern 302 and a hard mask including first patterns 310 on the cell region C and second patterns 312 on the peripheral region P. A first trench 315 and a second trench 317 may be formed in the substrate 300. The first trench 315 may be formed in the cell region C and the second trench 317 may be formed in the peripheral region P. The first trench 315 may have a first width and the second trench 317 may have a second width. The second width may be substantially wider than the first width.

The hard mask, the pad oxide layer pattern 302, and the first and second trenches 315 and 317 may be formed by the same or a similar process to those described with reference to FIGS. 4 to 6. Thus, further detailed description of the processes forming the hard mask, the pad oxide layer pattern 302 and the first and second trenches 315 and 317 is omitted.

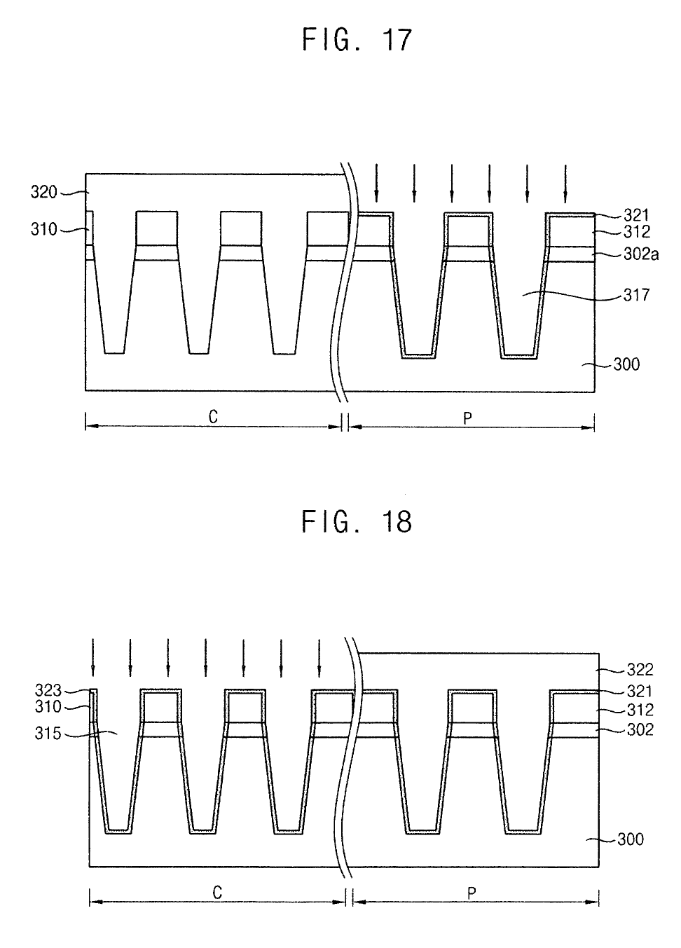

Referring to FIG. 17, a first photoresist pattern 320 may be formed on the cell region C. The first photoresist pattern 320 may cover the cell region C and may expose the peripheral region P.

A first plasma doping process may be performed on the peripheral region P of the substrate 300 using the first photoresist pattern 320 as an implant mask to implant a first impurity on the peripheral region P including the second trench 217. The first plasma doping process may include plasma doping at an implantation dose of about 1.0×10¹⁴ atoms/cm² to about 1.0×10¹⁷ atoms/cm². The first plasma doping process may be performed at a pressure of about 10 torr to about 100 torr. A first impurity region 321 may be formed on surfaces of the second patterns 312 and along profiles of the second trench 317 by the first plasma doping process.

The first impurity may accelerate a subsequent oxidation process. Accordingly, when an oxide layer is formed in a single atmosphere, the oxide layer on a portion of the substrate into which the first impurity has been implanted may be substantially thicker than the oxide layer on a portion of the substrate into which the first impurity has not been implanted. The first impurity may include the same oxidation accelerating impurity described above. In an implementation, the first impurity may include, e.g., a fluorine atom and/or an argon atom.

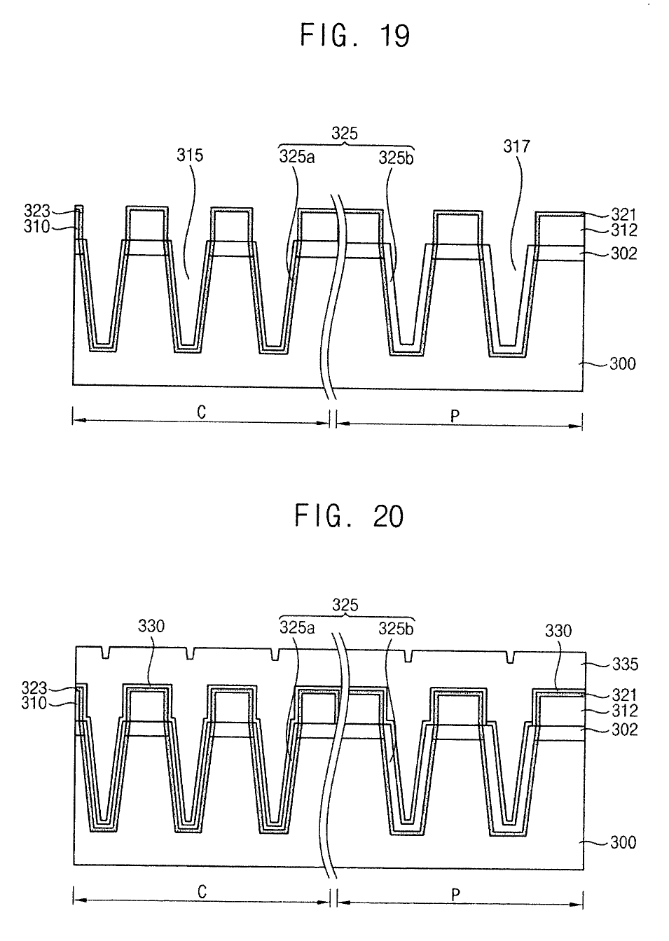

The first impurity may be uniformly implanted into the peripheral region P including the second trench 317 by the first plasma doping process. Thus, when the oxide layer 325 (see FIG. 19) is formed on the second trench 317 in a subsequent process, the thick oxide layer 325b on the peripheral region P (see FIG. 19) having a uniform thickness may be formed along the surface of the second trench 317. After performing the first plasma doping process, the first photoresist pattern 320 may be removed from the cell region C.

The ion implantation process may be easily influenced by, e.g., an angle of the first impurity implantation, an energy, a state of the substrate 300, etc., and if not properly performed, the first impurity may not be uniformly implanted on the peripheral region P having the second trench 317. Thus, the first impurity may be implanted on only an upper portion or a lower portion of the second trench 317 without being conformally implanted along the surface of the second trench 317. Accordingly, when the oxide layer 325 is formed on the second trench 317 in a subsequent process, the oxide layer 325 formed on the second trench 317 may not have the desired uniform thickness.

Referring to FIG. 18, a second photoresist pattern 322 may be formed on the peripheral region P. The second photoresist pattern 322 may cover the peripheral region P and may expose the cell region C.

A second plasma doping process may be performed on the cell region C of the substrate 300 using the second photoresist pattern 322 as an implant mask to implant a second impurity on the cell region C including the first trench 315. The second plasma doping process may include plasma doping at an implantation dose of about 1.0×10¹⁴ atoms/cm² to about 1.0×10¹⁷ atoms/cm². The second plasma doping process may be performed at a pressure of about 10 torr to about 100 torr A second impurity region 323 may be formed on surfaces of the first patterns 310 and along profiles of the first trench 315 by the second plasma doping process.

The second impurity may retard a subsequent oxidation process. Therefore, when the oxide layer 325 is formed in a single atmosphere, the oxide layer on a portion of the substrate 300 into which the second impurity has been implanted may be substantially thinner than the oxide layer on a portion of the substrate 300 into which the second impurity has not been implanted. The second impurity may include the same oxidation retarding impurity described above. In an implementation, the second impurity may include, e.g., a nitrogen atom.

The second impurity may be uniformly implanted into the cell region C including the first trench 315 having a narrow first width and a high aspect ratio by the second plasma doping process. When the first trench 315 has the high aspect. ratio, the second impurity may be conformally implanted along a surface of the first trench 315 by the second plasma doping process. Thus, when the oxide layer 325 is formed on the first trench 315 in a subsequent process, the thin first oxide layer 325a having a uniform thickness may be formed along the surface of the first trench 315 on the cell region C. After performing the second plasma doping process, the second photoresist pattern 322 may be removed from the peripheral region P.

Referring to FIG. 19, the oxide layer 325 including the first oxide layer 325a and the second oxide layer 325b may be formed on the substrate 300 including the cell region C and the peripheral region P. The first oxide layer 325a may be disposed on the cell region C and the second oxide layer 325b may be disposed on the peripheral region P.

The cell region C may include the NMOS and the peripheral region P may include the PMOS and the NMOS. As mentioned above, the first oxide layer 325a on the cell region C may be relatively thin and the second oxide layer 325b on the peripheral region P may be relatively thick in order to prevent deterioration, e.g., HEIP. Further, the oxide layer 325 may be conformally formed along profiles of surfaces of the first and second trenches 315 and 317.

A thickness of the oxide layer 325 may be adjusted or determined by the first impurity and/or the second impurity. The oxidation accelerating first impurity may be included in the peripheral region P having the second trench 317 so that the second oxide layer 325b on the peripheral region P may be thick enough to prevent deterioration. The oxidation retarding second impurity may be included in the cell region C including the first trench 315 having the narrow first width so that the first oxide layer 325a on the cell region C may be thin enough to be conformally formed along profiles of the first trench 315. For example, the second oxide layer 325b on the peripheral region P may have a thickness of about 100 Å to about 200 Å and the first oxide layer 325a on the cell region C may have a thickness less than about 100 Å. As mentioned above, the first and second impurities may be uniformly implanted along the profiles of the surface of the first and second trenches 315 and 317 so that the oxide layer 325 on the first and second trenches 315 and 317 may have a uniform thickness.

Referring to FIG. 20, the liner 330 and an isolation layer 335 may be formed on the oxide layer 325. The liner 330 may be conformally formed on the oxide layer 325 along profiles of the first trench 315 and the second trench 317. The isolation layer 335 may be formed on the liner 330 to fill the first trench 315 and the second trench 317. The isolation layer 335 may include, e.g., an oxide, a nitride, etc. In an implementation, the isolation layer 335 may include, e.g., silicon oxide, having superior gap-filling characteristics.

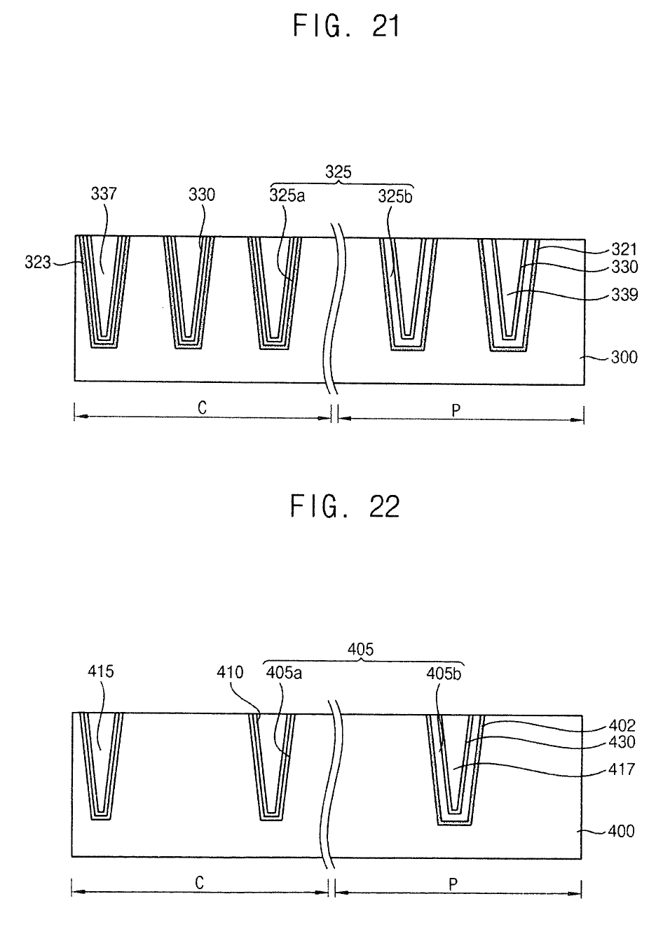

Referring to FIG. 21, the pad oxide layer pattern 302, the hard mask, and portions of the isolation layer 335 may be removed such that a portion of the substrate 300 is exposed. A first isolation layer pattern 337 in the cell region C and the second isolation layer pattern 339 in the peripheral region P may remain to fill the first trench 315 and the second trench 317, respectively. The pad oxide layer pattern 302, the hard mask, and the isolation layer 335 may be removed by, e.g., a CMP process and/or an etch-back process.

The first isolation layer pattern 337, the thin first oxide layer 325a, and the liner 330 may be disposed on the cell region C. The second isolation layer pattern 339, the thick second oxide layer 325b, and the liner 330 may be disposed on the peripheral region P. Additionally, the cell region C may include the second impurity region 323 in the substrate 300 adjacent to the thin first oxide layer 325a. The second impurity region 323 may include the oxidation retarding second impurity. The peripheral region P may include the first impurity region 321 in the substrate 300 adjacent to the thick second oxide layer 325b. The first impurity region 321 may include the oxidation accelerating first impurity.

The first and second isolation layer patterns 337 and 339 may divide the substrate 300 into an active region and an inactive region. A gate structure may be formed on the active region.

Prior to the oxidation process, the oxidation accelerating first impurity and the oxidation retarding second impurity may be implanted into the peripheral region P including the second trench 317 and the cell region C including the first trench 215, respectively. Thus, the thin first oxide layer 325a may be formed on the cell region C and the thick second oxide layer 325b may be formed on the peripheral region P by a single oxidation process.

Additionally, the first and second impurities adjusting or determining the oxidation process may be uniformly implanted along profiles of the first trench 315 having a high aspect ratio and the second trench 317 by the plasma doping process. As a result, the first oxide layer 325a and the second oxide layer 325b having a uniform thickness may be formed on the substrate 300 including the first and second trenches 315 and 317, respectively.

The oxide layer 325 may include the thin first oxide layer 325a on the cell region C and the thick second oxide layer 325b on the peripheral region P. As a result, the first oxide layer 325a on the cell region C may be thin enough to be conformally formed along profiles of the first trench 315 having a high aspect ratio. The second oxide layer 325b on the peripheral region P may be thick enough to prevent deterioration, e.g., HEIP. Thus, deterioration of a semiconductor device may be prevented so that the semiconductor device may have good electrical characteristics and reliability.

Hereinafter, a method of manufacturing a semiconductor device according to an embodiment will be explained in detail with reference to the accompanying drawings. FIGS. 22 to 34 illustrate cross-sectional views of a method of manufacturing a semiconductor device in accordance with an embodiment. Although FIGS. 22 to 34 illustrate the method of manufacturing a DRAM device, the features and advantages of the embodiments may be employed in other volatile semiconductor devices or nonvolatile semiconductor devices.

Referring to FIG. 22, a substrate 400 including a cell region C and a peripheral region P may be provided. The substrate 400 may include a cell region C in which memory cells may be arranged and a peripheral region P in which circuit cells may be arranged. In order to constitute a CMOS circuit, an NMOS may be formed in the cell region C, and an NMOS and a PMOS may be formed in the peripheral region P. For example, the NMOS may be formed in the cell region C and the NMOS of the peripheral region P may be substantially closer to the cell region C than the PMOS of the peripheral region P.

The substrate 400 may include an oxide layer 405 including a first oxide layer 405a and a second oxide layer 405b, a liner 410, a first isolation layer pattern 415, and a second isolation layer pattern 417. The first oxide layer 405a, the liner 410, and the first isolation layer pattern 415 may be disposed on the cell region C. The second oxide layer 405b, the liner 410, and the second isolation layer pattern 417 may be disposed on the peripheral region P.

An impurity region may be formed on the substrate 400. In an implementation, a first impurity region 402 may be formed only on the peripheral region. The first impurity region 402 may include an oxidation accelerating first impurity. The first impurity may include the same oxidation accelerating impurity described above. In an implementation, the first impurity may include, e.g., an argon atom and/or a fluorine atom. The first impurity may be implanted by, e.g., a plasma doping process, to be uniformly doped along profiles of a trench in the peripheral region P. In another implementation (not illustrated), a second impurity region may be formed only on the cell region C. The second impurity region may include an oxidation retarding second impurity. The second impurity may include the same oxidation retarding impurity described above. In an implementation, the second impurity may include, e.g., a nitrogen atom. The second impurity may be implanted by, e.g., a plasma doping process, to be uniformly doped along profiles of a trench having a high aspect ratio in the cell region C. In still another implementation (not shown), both the first impurity region 402 and the second impurity region may be formed on the peripheral region P and the cell region C, respectively. The first impurity region 402 may include the oxidation accelerating first impurity and the second impurity region may include the oxidation retarding second impurity.

The oxide layer 405 may include the thin first oxide layer 405a on the cell region C and the thick second oxide layer 405b on the peripheral region P. The first oxide layer 405a on the cell region C may be thin enough to be conformally formed along profiles of the trench having a high aspect ratio in the cell region C. The second oxide layer 405b on the peripheral region P may be thick enough to prevent the deterioration of semiconductor devices, e.g., HEIP, caused by the liner 410 on the peripheral region P including the PMOS.

The first isolation layer pattern 415 and the second isolation layer pattern 417 may divide the substrate 400 into an active region and an inactive region. A gate structure may be formed on the active region.

The first impurity region 402, the oxide layer 405, the liner 410, and the first and second isolation layer patterns 415 and 417 may be formed by the same or similar processes as those described above with reference to FIGS. 4 to 10, FIGS. 11 to 15, and FIGS. 16 to 21. Thus, further detailed description of the processes forming the first impurity region 402, the oxide layer 405, the liner 410, and the first and second isolation layer patterns 415 and 417 is omitted.

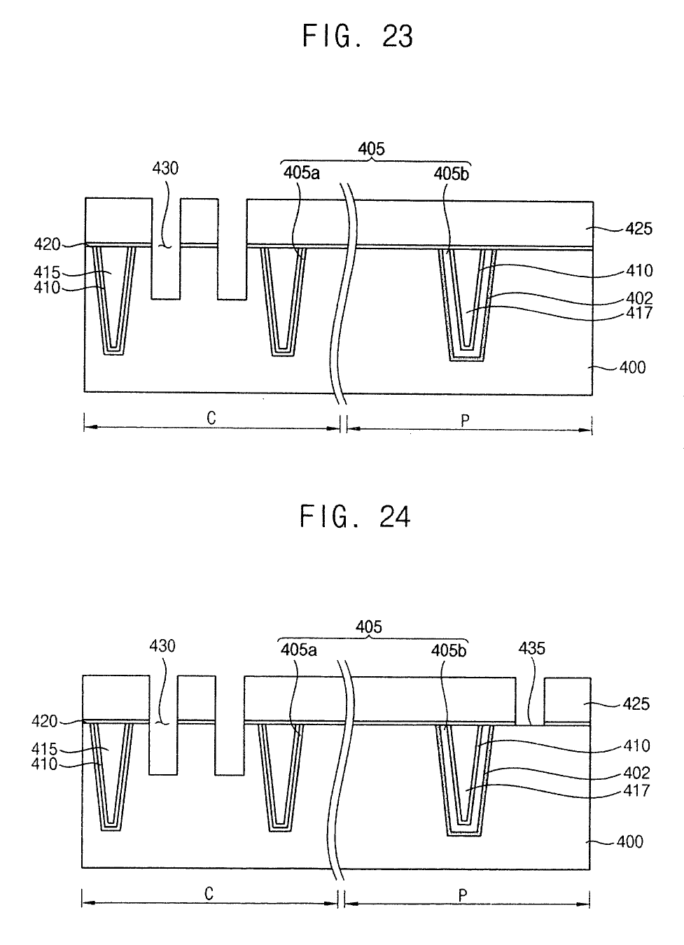

Referring to FIG. 23, a buffer layer 420 may be formed on the substrate 400. The buffer layer 420 may be formed by, e.g., a thermal oxidation process. The buffer layer 420 may have a thickness of about 50 Å to about 150 Å.

A hard mask layer 425 may be formed on the buffer layer 420. The hard mask layer 425 may include, e.g., a material having an etching rate different from etching rates of the substrate 400 and the buffer layer 420. For example, the hard mask layer 425 may include a silicon nitride layer.

A first gate mask layer (not illustrated) may be formed on the hard mask layer 425. The first gate mask layer may have a multi-layer structure. For example, the first gate mask layer may include a lower layer, a middle layer, and an upper layer. The lower layer may include, e.g., an oxide layer formed by a CVD process, and may have a thickness of about 2,000 Å to about 3,000 Å. The middle layer may include, e.g., an organic layer such as an amorphous carbon layer, and may have a thickness of about 2,000 Å to about 3,000 Å. The upper layer may include, e.g., an anti-reflective layer such as a nitride layer, and may have a thickness of about 500 Å.

The first gate mask layer may expose at least a portion of the cell region C and cover the peripheral region P. The hard mask layer 425 may be patterned using the first gate mask layer as an etching mask to expose a portion of the buffer layer 420 on the cell region C.

The substrate 400 and the buffer layer 420 in the cell region C may be etched using the hard mask layer 425 as an etch mask to form a preliminary first opening. A first etch stop layer (not illustrated) may be formed on a side surface and a bottom surface of the preliminary first opening. The first etch stop layer may include, e.g., a nitride layer having a thickness of about 200 Å. An etch-back process may be performed on the first etch stop layer to remove a portion of the first etch stop layer on the bottom surface of the preliminary first opening. Thus, a portion of the first etch stop layer on the side surface may remain.

The bottom surface of the preliminary first opening may be etched using the first etch stop layer as an etch mask to form a first opening 430. In an implementation, the bottom surface of the preliminary first opening may be anisotropically etched to form the first opening 430. In another implementation, the bottom surface of the preliminary first opening may be isotropically etched to form the first opening 430 having a lower portion that is substantially wider than an upper portion.

Referring to FIG. 24, the hard mask layer 425 on the peripheral region P may be patterned to form a second hole 435. The second hole 435 may expose a portion of the substrate 400 on the peripheral region P.

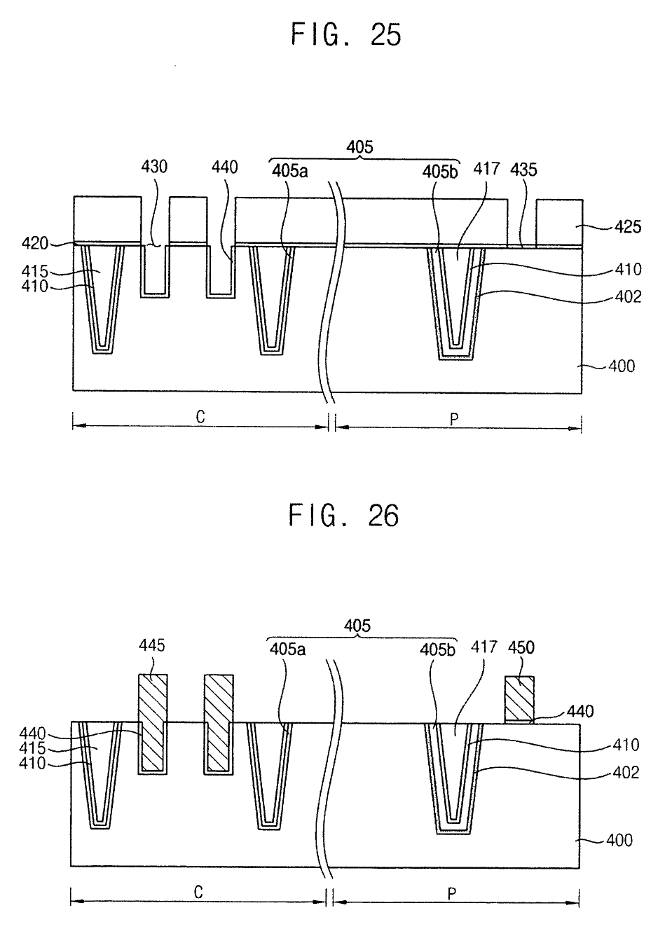

Referring to FIG. 25, a gate insulating layer 440 may be formed on the side surface and the bottom surface of the first opening 430 and a bottom surface of the second opening 435. The gate insulating layer 440 may include, e.g., a hafnium oxide layer, a tantalum oxide layer, an oxide/nitride/oxide layer, etc.

Referring to FIG. 26, a first gate electrode 445 and a second gate electrode 450 may be formed on the substrate 400. The first gate electrode 445 may be formed on the cell region C and the second gate electrode 450 may be formed on the peripheral region P. The first gate electrode 445 and the second gate electrode 450 may include, e.g., polysilicon. After forming the first and second gate electrodes 445 and 450, the hard mask layer 425 and the buffer layer 420 may be removed from the substrate 400.

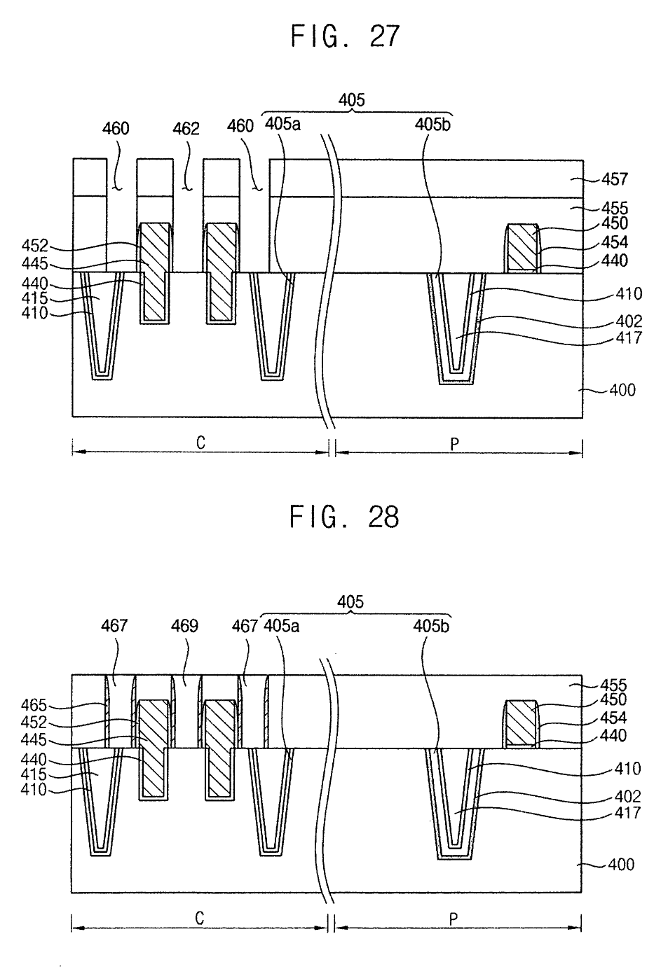

Referring to FIG. 27, a first spacer 452 may be formed on a sidewall of the first gate electrode 445 and a second spacer 454 may be formed on a sidewall of the second gate electrode 450. Impurities may then be implanted into the substrate 400 using the first and second gate electrodes 445 and 450 as an implantation mask to form source/drain regions (not illustrated) on the substrate 400. The impurities implanted may be different from the first and second impurities described above.

A first insulating interlayer 455 may be formed to cover the first and second gate electrodes 445 and 450. The first insulating interlayer 455 may include, e.g., BPSG, PSG, PE-TEOS, HDP-CVD oxide, etc. The first insulating interlayer 455 may be formed by, e.g., a CVD process, a HDP-CVD process, etc.

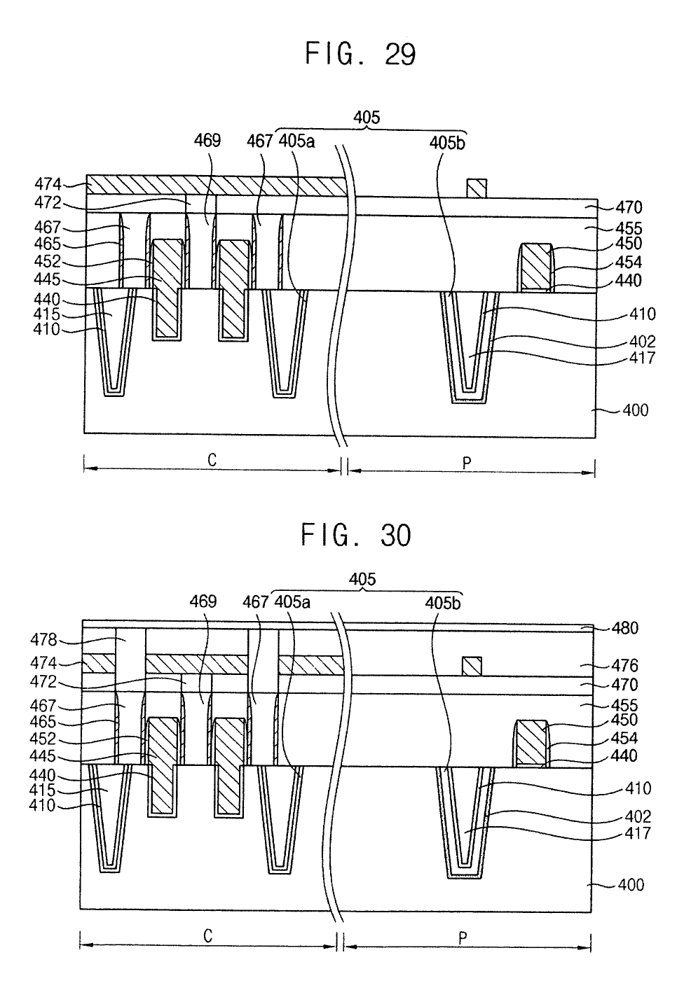

A first contact hole 460 and a second contact hole 462 may be formed in the first insulating interlayer 455. To form the first and second contact holes 460 and 462, a photoresist pattern 457 may be formed on the first insulating interlayer 455. The first insulating interlayer 455 may be etched using the photoresist pattern 457 as an etching mask to form the first and second contact holes 460 and 462 exposing the source/drain. A capacitor contact plug 467 (see FIG. 28) may be formed in the first contact hole 460 and a bit-line plug 469 (see FIG. 28), electrically connected to a bit-line 474 (see FIG. 29), may be formed in the second contact hole 462. After forming the first and second contact holes 460 and 462, the photoresist pattern 457 may be removed from the first insulating interlayer 455.

Referring to FIG. 28, a spacer 465 may be formed on sidewalls of the first and second contact holes 460 and 462. The spacer 465 may be formed from, e.g., silicon nitride by an etch-back process.

The first and second contact holes 460 and 462 may be filled with the capacitor contact plug 467 and the bit-line contact plug 469, respectively. The capacitor contact plug 467 and the bit-line contact plug 469 may include, e.g., a heavily doped polysilicon layer, a metal layer, a conductive metal nitride layer, etc.

Referring to FIG. 29, a second etch stop layer (not illustrated) and a second insulating interlayer 470 may be sequentially formed on the capacitor contact plug 467, the bit-line contact plug 469, and the first insulating interlayer 455. The second etch stop layer may be formed from, e.g., silicon nitride by a CVD process. The second insulating interlayer 470 may be formed from, e.g., BPSG, PSG, PE-TEOS, HDP-CVD oxide, etc., by a CVD process, a HDP-CVD process, etc.

A mask (not illustrated) may be formed on the second insulating interlayer 470. The second insulating interlayer 470 may be etched using the mask as an etch mask to form bit line contact hole exposing the bit line contact plug 469. A conductive layer may then be formed on the second insulating interlayer 470 to form a bit line 474 and a bit line contact 472.

Referring to FIG. 30, a third insulating interlayer 476 may be formed to cover the bit line 474. The third insulating interlayer 476 may include, e.g., BPSG, PSG, PE-TEOS, HDP-CVD oxide, etc., formed by a CVD process, a HDP-CVD process, etc.

A photoresist pattern (not shown) may be formed on the third insulating interlayer 476. The third insulating interlayer 476 may be etched using the photoresist pattern as an etch mask to form a contact hole exposing the capacitor contact plug 467.

The contact hole may be filled with a capacitor contact pad 478 electrically connected to the capacitor contact plug 467. The capacitor contact pad 478 may include, e.g., a heavily doped polysilicon layer. A third etch stop layer 480 may be formed on the third insulating interlayer 476 and the capacitor contact pad 478.

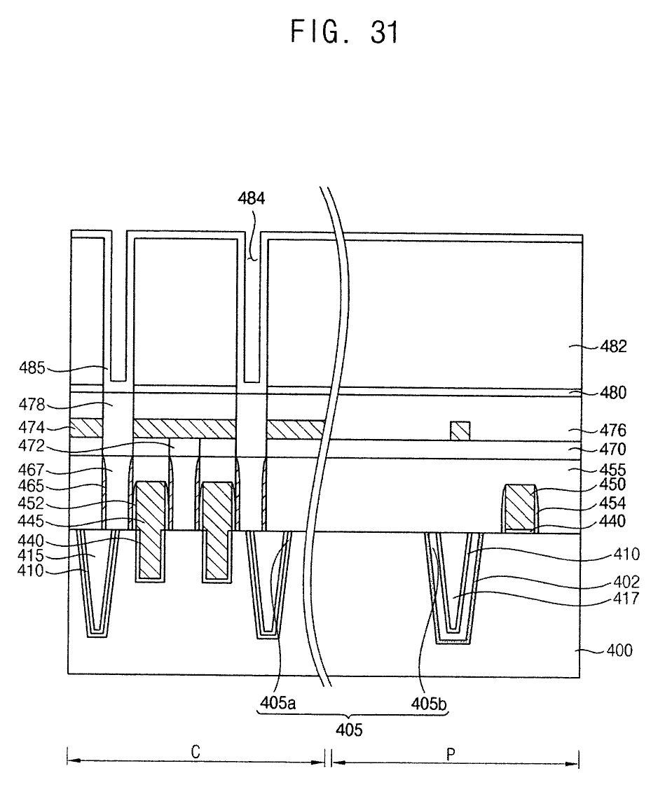

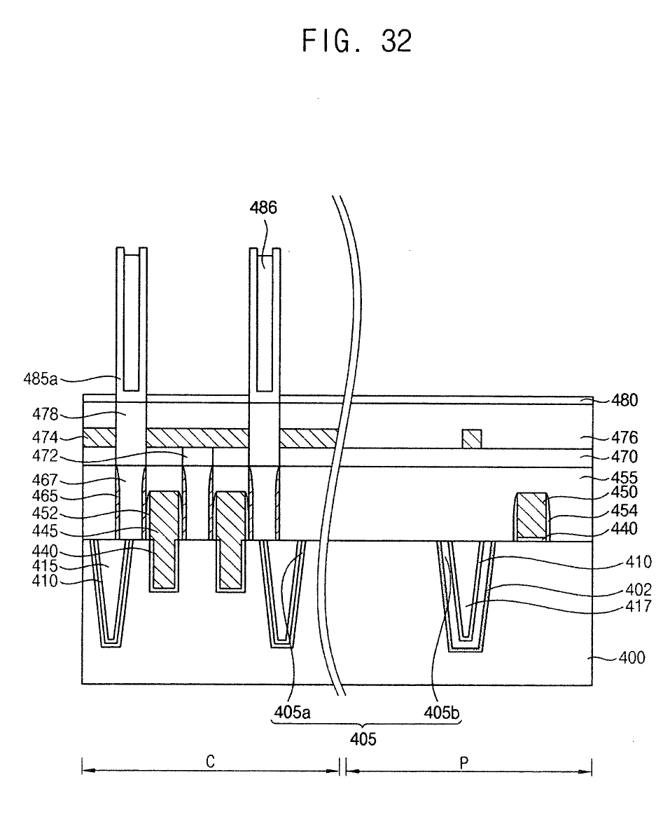

Referring to FIG. 31, a mold layer 482 may be formed on the third etch stop layer 480. The mold layer 482 may have a total thickness of about 10,000 Å to about 20,000 Å. The mold layer 482 may include, e.g., an oxide layer formed by a CVD process. Alternatively, the mold layer 482 may include different materials having different etch ratios for readily forming a hole where a capacitor may be formed.

A mask (not illustrated) may be formed on the mold layer 482. The mold layer 482 may be etched using the third etch stop layer 480 as an etch endpoint to form an opening 484 for forming the capacitor. The opening 484 may be formed by, e.g., a dry etch process.

Portions of the third etch stop layer 480 on the capacitor contact pad 478 and the mask on the mold layer 482 may then be removed. A lower electrode layer 485 may then be formed on an upper surface of the mold layer 482 and an inner surface of the opening 484. The lower electrode layer 485 may include, e.g., TiN, Ti, TaN, Pt. etc. The lower electrode layer 485 may have a characteristic capable of closely contacting the capacitor contact pad 478. The third etch stop layer 480 may have a sufficient thickness for supporting a lower electrode 485a (see FIG. 32) to prevent the lower electrode 485a from collapsing during removal of the mold layer 482.

Referring to FIG. 32, a buried layer 486 may be formed on the lower electrode layer 485. The buried layer 486 may include, e.g., Tonen Silazene (TOSZ), having a good gap-filling characteristic. Alternatively, the buried layer 486 may include a material having an etch ratio different from that of the mold layer 482, e.g., an organic layer to prevent collapse of the lower electrode 485a.

The buried layer 486 may be planarized by an etch-back process. Simultaneously, upper portions of the lower electrode layer 485 may be removed to form the lower electrode 485a having a cylindrical shape. The upper portions of the lower electrode layer 485 may be removed by, e.g., a wet etch-back process.

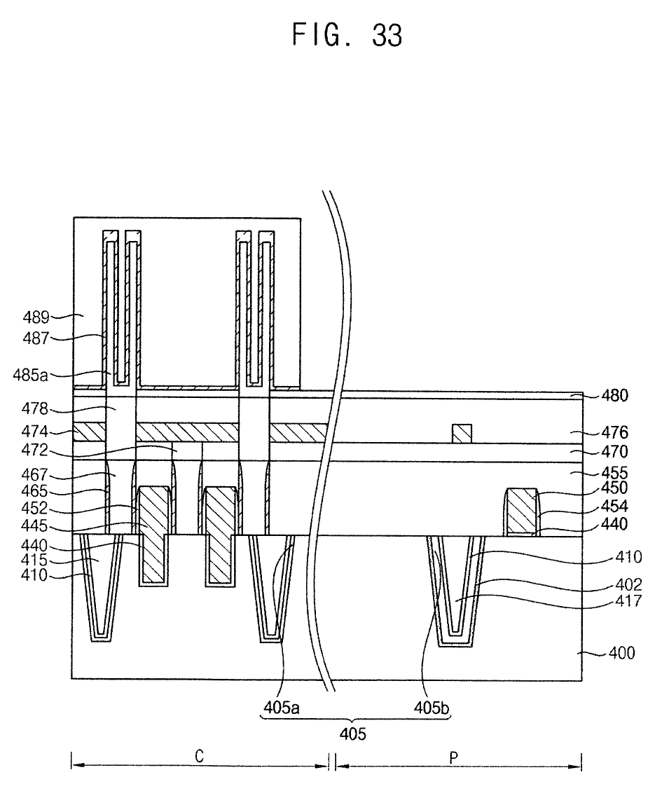

If the lower electrode 485a has a sharp upper end, the sharp upper end may cut a dielectric layer 487 (see FIG. 33) thereon, thereby generating an undesirable leakage current. Thus, in order to prevent the upper end of the lower electrode 485a from being sharpened, the lower electrode layer 485 may be, e.g., wet-etched, to provide the upper end of the lower electrode 485a with a smooth, rounded shape.

The mold layer 482 and the buried layer 486 may be removed by, e.g., a lift-off process. During the removal process, it may be used to prevent the adjacent lower electrodes 485a from being adhered.

In order to prevent collapse of the lower electrode 485a, a structure may be provided to the lower electrode 485a. The structure may have, e.g., a ladder shape, an annular shape, etc.

Referring to FIG. 33, a dielectric layer 487 may be formed on the lower electrode 485a. The dielectric layer 487 may include, e.g., a zirconium oxide layer formed by an atomic layer deposition (ALD) process. For example, a precursor may be applied to the lower electrode 485a in an ALD chamber. The precursor may include, e.g., tetrakis(ethylmethylamino)zirconium (TEMAZ). The precursor may be chemisorbed with the lower electrode 485a. A purge gas may be introduced into the chamber to remove non-reacted gases. The purge gas may include, e.g., argon, helium, nitrogen, etc. When the non-reacted gases are removed, the chemisorbed layer on the lower electrode 485a may have an atomic thickness. Here, because the chemisorption process may be performed at a low temperature of, e.g., about 250° C, the chemisorbed layer may be uniformly formed on the lower electrode 485a having a high aspect ratio. Further, because an opening of the cylindrical lower electrode 485a may not be clogged, the precursor may be uniformly distributed on a bottom surface of the cylindrical lower electrode 485a. Therefore, the capacitor may have good step coverage.

An oxidizing agent may be introduced into the chamber at a temperature of, e.g., about 275° C. The oxidizing agent may react with the precursor to form the zirconium oxide layer. The oxidizing agent may include, e.g., O₂, O₃, H₂O, etc. In an implementation, the oxidizing agent may include, e.g., O₃, a strong oxidizer. Carbon or nitrogen in the precursor may be removed to form the zirconium oxide layer. This cycle may be repeated, e.g., dozens of times, to form the zirconium oxide layer having a desired thickness. In an implementation, the cycle may be repeated, e.g., about 100 times to about 150 times, to form the zirconium oxide layer having a thickness of, e.g., about 100 Å to about 150 Å.

Additionally, a zirconium oxynitride layer (not illustrated) may be formed on the zirconium oxide layer. Thus, the dielectric layer 487 may have a multi-layered structure including, e.g., the zirconium oxide layer and the zirconium oxynitride layer. Alternatively, the dielectric layer 487 may include materials having diverse dielectric constants, e.g., ZrO₂/Al₂O₃/ZrO₂ (ZAZ), ZrO₂/Al₂O₃/TaO₂ (ZAT), Hf₂O₃, etc. An upper electrode 489 may be formed on the dielectric layer 487. The upper electrode 489 may include, e.g., TiN, Ti, TaN, Pt, etc.

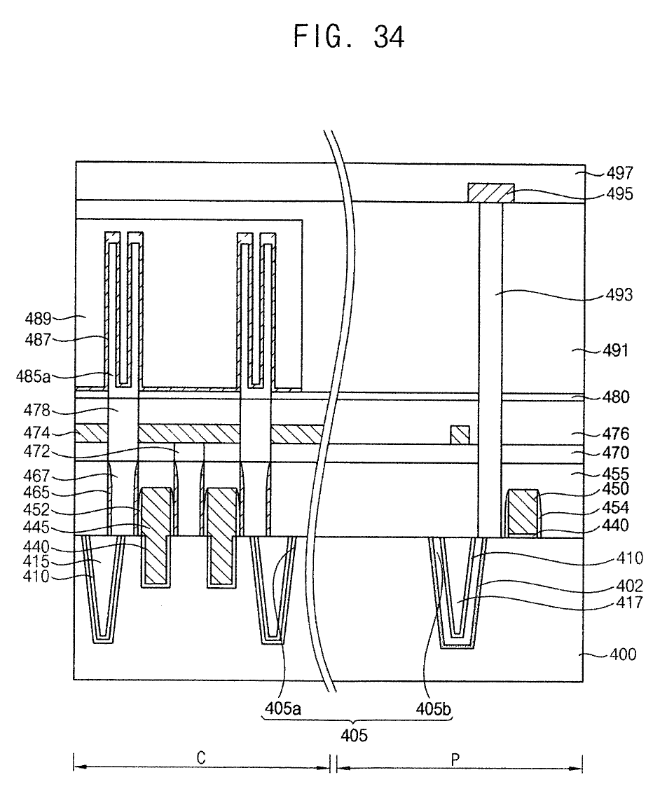

Referring to FIG. 34, a fourth insulating interlayer 491 may be formed on the upper electrode 489 and the second etch stop layer 480. The fourth insulating interlayer 491 may remove a step difference between the cell region C and the peripheral region P. The fourth insulating interlayer 491 may be formed using, e.g., BPSG, PSG, PE-TEOS, HDP-CVD oxide, etc., by a CVD process, a HDP-CVD process, etc. A planarization process may be performed on the fourth insulating interlayer 491 by, e.g., a self-stopping chemical mechanical polishing process. A metal contact 493 and a metal wiring 495 may be formed and then a protection layer 497 may be formed on the fourth insulating interlayer 491.

According to an embodiment, the DRAM device may include the cell region C having the thin oxide layer 405a and the peripheral region P having the thick oxide layer 405b. That is, the oxidation retarding second impurity may be implanted in the cell region C or the oxidation accelerating first impurity may be implanted in the peripheral region P before the oxide layer 405 is formed. Thus, when the oxidation process is performed on the substrate 400, the first oxide layer 405a having a thin thickness may be selectively formed on the cell region C or the second oxide layer 405b having a thick thickness may be selectively formed on the peripheral region P.

Additionally, the oxidation retarding and/or accelerating impurity may be uniformly implanted by the plasma doping process. Thus, the first oxide layer 405a and/or the second oxide layer 405b may have a uniform thickness on the cell region C and/or the peripheral region P, respectively. Thus, deterioration of the DRAM device may be prevented so that the semiconductor device may have good electrical characteristics and reliability.

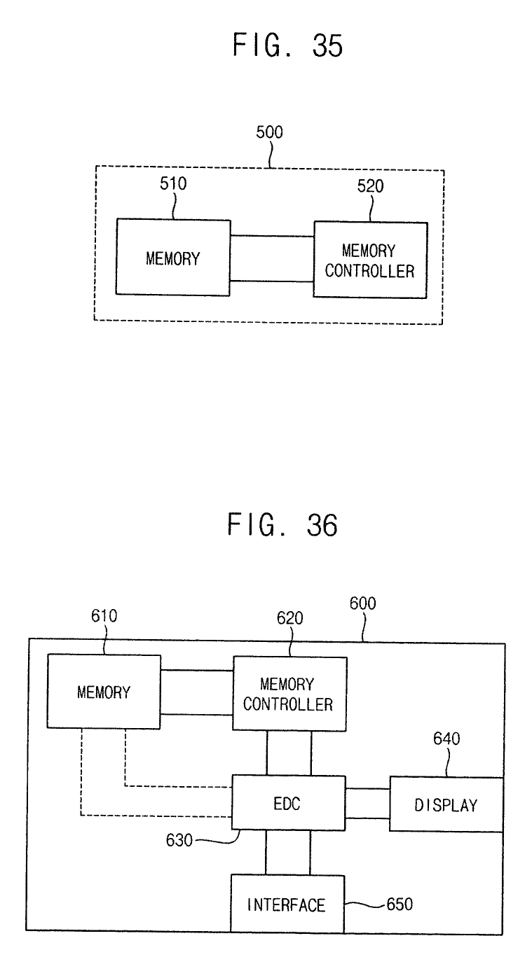

Hereinafter, a system according to an embodiment will be explained in detail with reference to the accompanying drawings. FIG. 35 illustrates a block diagram of a system including a DRAM device having a thin oxide layer on a cell region and a thick oxide layer on a peripheral region in an isolation layer.

Referring to FIG. 35, a system 500 may include a memory 510 and a memory controller 520 connected with the memory 510. The memory 510 may include a DRAM device having an isolation layer which includes a thin oxide layer on a cell region and a thick oxide layer on a peripheral region according to an embodiment. The memory controller 520 may input control signals for controlling operations of the memory 510 into the memory 510. The system 500 may control data from a host or data in the memory 510 based on the control signals. The system 500 may be applied to diverse digital devices including memory, e.g., a digital camera, a cellular phone, etc.

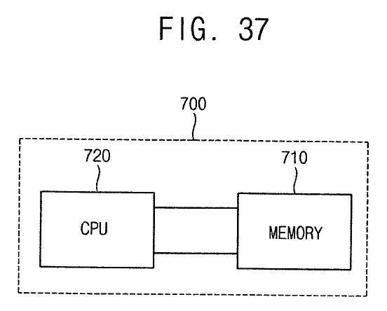

FIG. 36 illustrates a block diagram of a system including a DRAM device having a thin oxide layer on a cell region and a thick oxide layer on a peripheral region in an isolation layer according to an embodiment. Referring to FIG. 36, the system 600 may include a portable device having a memory 610 and a memory controller 620. Thus, the memory 610 may include a DRAM device having an isolation layer which includes a thin oxide layer on a cell region and a thick oxide layer on a peripheral region.

The portable device 600 may include, e.g., an MP3 player, a video player, a portable multi-media player, etc. The portable device 600 may include, e.g., the memory 610, the memory controller 620, an encoder/decoder (EDC) 630, a display 640, and an interface 650.

Data may be inputted/outputted into/from the memory 610 through the memory controller 620 by the encoder/decoder 630. As illustrated by dotted lines in FIG. 36, the data may be directly inputted into the memory 610. Also, the data may be outputted to the encoder/decoder 630 from the memory 610.

The encoder/decoder 630 may encode the data in the memory 610. For example, the encoder/decoder 630 may perform an MP3 encoding and a PMP encoding for storing the data in an audio player and a video player. Alternatively, the encoder/decoder 630 may perform an MPEG encoding for storing video data in the memory 610. Further, the encoder/decoder 630 may include a multi-encoder for encoding data having different types in accordance with different formats. For example, the encoder/decoder. 630 may include an MP3 encoder for audio data and an MPEG encoder for video data.

The encoder/decoder 630 may decode the data from the memory 610. For example, the encoder/decoder 630 may perform an MP3 decoding and a PMP decoding according to data outputted in an audio player and a video player. Alternatively, the encoder/decoder 630 may perform an MPEG decoding according to data outputted from the memory 610. For example, the encoder/decoder 630 may include an MP3 decoder for audio data and an MPEG decoder for video data.

In an implementation, the encoder/decoder 630 may include only a decoder. For example, the decoder may receive and transmit data to the memory controller 620 or the memory 610.

The encoder/decoder 630 may receive data for encoding or encoded data through the interface 650. The interface 650 may include, e.g., a USB interface or a Firewire interface. The data may be outputted from the interface 650 to the memory 610.

The display 640 may display the data outputted from the memory 610 or decoded by the encoder/decoder 610. The display 640 may include, e.g., a speaker jack for outputting audio data, a display screen for outputting video data, etc.

FIG. 37 illustrates a block diagram of a system including a DRAM device having a thin oxide layer on a cell region and a thick oxide layer on a peripheral region in an isolation layer according to an embodiment. Referring to FIG. 37, the system 700 may include the memory 710 and a CPU 720. The memory 710 may be connected with the CPU 720 in a computer system 700. The memory 710 may include a DRAM device having an isolation layer which includes a thin oxide layer on a cell region and a thick oxide layer on a peripheral region; The computer system 700 may include, e.g., a desk top computer or a notebook computer, using the DRAM as a storage medium. Further, the system 700 may include other digital devices including, e.g., the memory 710 for storing data and controlling operations. The memory 710 may be directly connected or indirectly connected via a bus with the CPU 720.

According to an embodiment, a cell region may include a thin oxide layer and a liner and a peripheral region may include a thick oxide layer and a liner. Thus, the liner may be separated from a substrate by the thick oxide layer in the peripheral region so that a deterioration, e.g., HEIP, of the semiconductor device caused by the liner may be prevented when a PMOS is formed on the peripheral region. A system including the semiconductor device in accordance with an embodiment may be employed for a digital product to improve a performance of the digital product.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A method of forming an oxide layer on a trench, comprising:
forming a first trench in a first portion of a substrate and a second trench in a second portion of the substrate, the first portion being different from the second portion;
performing a plasma doping process on at least one of the first portion and the second portion to implant an impurity therein; and
performing an oxidation process to form an oxide layer on the substrate, a thickness of the oxide layer being determined by the impurity implanted in the substrate.

2. The method as claimed in claim 1, wherein performing the plasma doping process includes performing a first plasma doping process on the first portion to implant an oxidation retarding first impurity in the first portion having the first trench.

3. The method as claimed in claim 2, wherein the first impurity includes a nitrogen atom.

4. The method as claimed in claim 2, further comprising forming a first photoresist pattern covering the second portion of the substrate and exposing the first portion of the substrate prior to performing the first plasma doping process.

5. The method as claimed in claim 1, wherein performing the plasma doping process includes performing a second plasma doping process on the second portion to implant an oxidation accelerating second impurity in the second portion having the second trench.

6. The method as claimed in claim 5, wherein the second impurity includes at least one of a Group XVII element and a Group XVIII element on the periodic table.

7. The method as claimed in claim 6, wherein the second impurity includes at least one of a fluorine atom and an argon atom.

8. The method as claimed in claim 5, further comprising forming a second photoresist pattern covering the first portion of the substrate and exposing the second portion of the substrate prior to performing the second plasma doping process.

9. The method as claimed in claim 1, wherein performing the plasma doping process includes:
performing a first plasma doping process on the first portion to implant an oxidation retarding first impurity in the first portion having the first trench, and
performing a second plasma doping process on the second portion to implant an oxidation accelerating second impurity in the second portion having the second trench.

10. The method as claimed in claim 1, wherein performing the plasma doping process includes:
forming a first photoresist pattern covering the second portion of the substrate and exposing the first portion of the substrate;
performing a first plasma doping process on the first portion using the first photoresist pattern as a mask to implant an oxidation retarding first impurity in the first portion having the first trench;
forming a second photoresist pattern covering the first portion of the substrate and exposing the second portion of the substrate; and
performing a second plasma doping process on the second portion using the second photoresist pattern as a mask to implant an oxidation accelerating second impurity in the second portion having the second trench.

11. The method as claimed in claim 1, wherein performing an oxidation process to form an oxide layer on the substrate includes forming oxide layers on the first and second portions of the substrate, and wherein the oxide layer on the second portion of the substrate is thicker than the oxide layer on the first portion of the substrate.

12. The method as claimed in claim 1, further comprising forming a nitride layer on the oxide layer.

13. The method as claimed in claim 1, wherein performing the plasma doping process includes plasma doping with an implantation dose of about 1.0×10¹⁴ atoms/cm² to about 1.0×10¹⁷ atoms/cm².

14. The method as claimed in claim 1, wherein the first trench and the second trench each have a width and the width of the second trench is larger than the width of the first trench.

15. The method as claimed in claim 1, wherein the first portion corresponds to a cell region and the second portion corresponds to a peripheral region.

16. The method as claimed in claim 1, wherein performing the plasma doping process includes plasma doping at a pressure of about 10 torr to about 100 torr.

17. A method of forming a semiconductor device, comprising:
providing a substrate including a cell region and a peripheral region;
forming a first trench in the cell region and a second trench in the peripheral region;
performing a plasma doping process on at least one of the cell region and the peripheral region to implant an impurity therein;
performing an oxidation process to form an oxide layer on the cell and peripheral regions of the substrate, such that a thickness of the oxide layer is determined by the impurity implanted in the substrate;
forming a nitride layer on the oxide layer; and
forming an isolation layer on the substrate to fill the first trench and the second trench.

18. The method as claimed in claim 17, further comprising:
forming a gate structure on the substrate including the isolation layer;
forming an insulation interlayer including a contact on the gate structure; and
forming a capacitor including a lower electrode, a dielectric layer, and an upper electrode on the contact.

19-22. (canceled)
